(19) United States
(12) Patent Application Publication
(10) Pub. No.: US 2025/0300433 A1
(43) Pub. Date: Sep. 25, 2025

(54) QUANTUM CASCADE LASER

(71) Applicant: HAMAMATSU PHOTONICS K. K., Hamamatsu-shi (JP)

(72) Inventors: Akio ITO, Hamamatsu-shi (JP); Kazuue Fujita, Hamamatsu-shi (JP); Shohei Hayashi, Hamamatsu-shi (JP)

(73) Assignee: HAMAMATSU PHOTONICS K. K., Hamamatsu-shi (JP)

(21) Appl. No.: 19/060,967

(22) Filed: Feb. 24, 2025

(30) Foreign Application Priority Data
Mar. 22, 2024 (JP) 2024-046743

(51) Int. Cl. H01S 5/34; H01S 5/042; H01S 5/343

(52) U.S. Cl. CPC H01S 5/3402; H01S 5/04256; H01S 5/34313

(57) ABSTRACT

A quantum cascade laser includes a semiconductor substrate having a first surface and a second surface, a semiconductor stacked body that includes an active layer having a cascade structure and is formed on the first surface, a first electrode formed a surface of the semiconductor stacked body, and a second electrode formed on the second surface. The semiconductor substrate is an InP substrate with a carrier density of 1×10¹⁷ cm⁻³ or less. A concave portion that passes through the semiconductor substrate and reaches the semiconductor stacked body is formed in the second surface. The second electrode is continuously formed on the second surface of the semiconductor substrate, on side surfaces of the concave portion, and on an exposed surface of the semiconductor stacked body which is exposed from the semiconductor substrate at the bottom of the concave portion.

### TECHNICAL FIELD

An aspect of the present disclosure relates to a quantum cascade laser.

### BACKGROUND

For example, in a quantum cascade laser described in International Publication WO 2021/125240, a semiconductor stacked body including an active layer is formed on a semiconductor substrate. In this quantum cascade laser, a pair of end surfaces of the active layer constitute a resonator that oscillates light of a first frequency and light of a second frequency, and a terahertz wave of a difference frequency between the first frequency and the second frequency is generated due to difference frequency generation.

### SUMMARY

### Technical Problem

In the quantum cascade laser described above, simplification in a structure and improvement in strength may be required. An objective of one aspect of the present disclosure is to provide a quantum cascade laser capable of simplifying a structure and improving a strength.

### Solution to Problem

A quantum cascade laser according to one aspect of the present disclosure is [1] “A quantum cascade laser including: a semiconductor substrate including a first surface, and a second surface on a side opposite to the first surface; a semiconductor stacked body that includes an active layer having a cascade structure and is formed on the first surface of the semiconductor substrate, in which the active layer is configured to generate and oscillate light of a first frequency and light of a second frequency, and generate a terahertz wave having a difference frequency between the first frequency and the second frequency by difference frequency generation; a first electrode formed on a surface of the semiconductor stacked body on a side opposite to the semiconductor substrate; and a second electrode formed on the second surface of the semiconductor substrate, wherein the semiconductor substrate is an InP substrate with a carrier density of 1×10¹⁷ cm⁻³ or less, a concave portion that passes through the semiconductor substrate and reaches the semiconductor stacked body is formed in the second surface of the semiconductor substrate, and the second electrode is continuously formed on the second surface of the semiconductor substrate, on side surfaces of the concave portion, and on an exposed surface of the semiconductor stacked body which is exposed from the semiconductor substrate at the bottom of the concave portion”.

In the quantum cascade laser, the semiconductor stacked body including the active layer is formed on the semiconductor substrate constituted by an InP substrate with a carrier density of 1×10¹⁷ cm⁻³ or less. Since the semiconductor substrate is less likely to absorb a terahertz wave, in the quantum cascade laser, the terahertz wave generated by difference frequency generation can be transmitted through the semiconductor substrate and emitted. On the other hand, since an InP substrate with a carrier density of 1×10¹⁷ cm⁻³ or less has insulating or semi-insulating properties, when such a semiconductor substrate is used, a pair of electrodes (anode and cathode) has been provided on a first surface side (semiconductor stacked body side) of the semiconductor substrate. However, in that case, a configuration of the first surface side may become complicated. In contrast, in the quantum cascade laser, the second electrode is formed on the second surface of the semiconductor substrate. More specifically, the concave portion that passes through the semiconductor substrate and reaches the semiconductor stacked body is formed in the second surface of the semiconductor substrate, and the second electrode is continuously formed on the second surface of the semiconductor substrate, on the side surfaces of the concave portion, and on the exposed surface of the semiconductor stacked body which is exposed from the semiconductor substrate at the bottom of the concave portion. When providing the second electrode on the second surface side of the semiconductor substrate in this manner, the configuration of the first surface side can be simplified as compared with a case where both the first electrode and the second electrode are provided on the first surface side. In addition, since the second electrode is continuously formed on the second surface of the semiconductor substrate, on the side surfaces of the concave portion, and on the exposed surface of the semiconductor stacked body, a strength as an element can be improved. Therefore, according to the quantum cascade laser, the structure can be simplified and the strength can be improved.

The quantum cascade laser according to one aspect of the present disclosure may be [2] “The quantum cascade laser according to [1], wherein the side surfaces of the concave portion include a first inclined surface inclined with respect to a stacking direction of the semiconductor stacked body so as to approach an outer edge of the semiconductor substrate as being far away from the semiconductor stacked body”. In this case, it is possible to suppress occurrence of step discontinuities (fracture at a step portion) in the second electrode continuously formed on the second surface of the semiconductor substrate, on the side surfaces of the concave portion, and on the exposed surface of the semiconductor stacked body.

The quantum cascade laser according to one aspect of the present disclosure may be [3] “The quantum cascade laser according to [2], wherein the semiconductor substrate further includes a substrate end surface that connects the first surface and the second surface, the substrate end surface includes an inclined end surface inclined with respect to the stacking direction to face a side opposite to the semiconductor stacked body, and an inclination angle of the first inclined surface with respect to the stacking direction is larger than an inclination angle of the inclined end surface with respect to the stacking direction”. In this case, the substrate end surface can be used as an emission surface from which a terahertz wave is emitted. In addition, occurrence of step discontinuities in the second electrode can be further suppressed.

The quantum cascade laser according to one aspect of the present disclosure may be [4] “The quantum cascade laser according to [3], wherein a length of the exposed surface of the semiconductor stacked body in an oscillation direction of the light of the first frequency and the light of the second frequency in the active layer is longer than a length of the inclined end surface in the oscillation direction”. In this case, the second electrode can be brought into contact with the semiconductor stacked body over a long distance in the oscillation direction, and the second electrode and the semiconductor stacked body can be electrically connected to each other in a satisfactory manner.

The quantum cascade laser according to one aspect of the present disclosure may be [5] “The quantum cascade laser according to any one of [2] to [4], wherein the first inclined surface is formed on a side surface from which the terahertz wave is emitted among the side surfaces of the concave portion”. In this case, it is possible to secure a large size (length) along an oscillation direction of a portion of the semiconductor stacked body on a side from which the terahertz wave is emitted. When using the portion as a transmission path for the terahertz wave generated in the active layer, the terahertz wave can be emitted in a satisfactory manner.

The quantum cascade laser according to one aspect of the present disclosure may be [6] “The quantum cascade laser according to any one of [1] to [5], wherein the side surfaces of the concave portion include a second inclined surface inclined with respect to a stacking direction of the semiconductor stacked body so as to be far away from an outer edge of the semiconductor substrate as being far away from the semiconductor stacked body”. In this case, since the second inclined surface is formed, the exposed surface of the semiconductor stacked body can be widened. As a result, the second electrode can be brought into contact with the semiconductor stacked body over a wide range, and the second electrode and the semiconductor stacked body can be electrically connected to each other in a satisfactory manner.

The quantum cascade laser according to one aspect of the present disclosure may be [7] “The quantum cascade laser according to any one of [1] to [6], wherein the side surfaces of the concave portion include a first inclined surface inclined with respect to a stacking direction of the semiconductor stacked body so as to approach an outer edge of the semiconductor substrate being far away from the semiconductor stacked body, and a second inclined surface inclined with respect to the stacking direction of the semiconductor stacked body so as to be far away from an outer edge of the semiconductor substrate as being far away from the semiconductor stacked body, and an inclination angle of the first inclined surface with respect to the stacking direction is larger than an inclination angle of the second inclined surface with respect to the stacking direction”. In this case, occurrence of step discontinuities in the second electrode can be further suppressed.

The quantum cascade laser according to one aspect of the present disclosure may be [8] “The quantum cascade laser according to any one of [1] to [7], wherein the semiconductor stacked body is formed on the semiconductor substrate so that a plurality of the active layers are arranged in a direction orthogonal to a stacking direction of the semiconductor stacked body, and the concave portion is formed so as to overlap the plurality of active layers when viewed from the stacking direction”. In this case, the quantum cascade laser including the plurality of active layers can be constituted in a satisfactory manner.

The quantum cascade laser according to one aspect of the present disclosure may be [9] “The quantum cascade laser according to any one of [1] to [8], wherein a surface of the first electrode on a side opposite to the semiconductor stacked body is flat”. In this case, epi-side-down mounting in which the quantum cascade laser is mounted on a mounting target so that the first electrode faces the mounting surface of the mounting target can be performed in a satisfactory manner.

According to one aspect of the present disclosure, it is possible to provide a quantum cascade laser capable of simplifying a structure and improving a strength.

### BRIEF DESCRIPTION OF THE DRAWINGS

FIG. 1 is a front elevational view of a quantum cascade laser according to an embodiment.

FIG. 2 is a cross-sectional view of a quantum cascade laser along line II-II in FIG. 1.

FIG. 3 is a view illustrating an example of a configuration of an active layer of the quantum cascade laser.

FIG. 4 is a perspective view of a quantum cascade laser according to a modification example when viewed from one side in a Z-direction.

FIG. 5 is a perspective view of the quantum cascade laser according to the modification example when viewed from the other side in the Z-direction.

FIG. 6 is a front elevational view of the quantum cascade laser according to the modification example.

FIG. 7 is a side view of the quantum cascade laser according to the modification example along line VI-VI in FIG. 5.

FIG. 8 is a plan view of the quantum cascade laser according to the modification example.

### DETAILED DESCRIPTION

Hereinafter, an embodiment of the present disclosure will be described in detail with reference to the accompanying drawings. In the following description, the same reference numeral will be given to the same or equivalent element, and redundant description will be omitted.

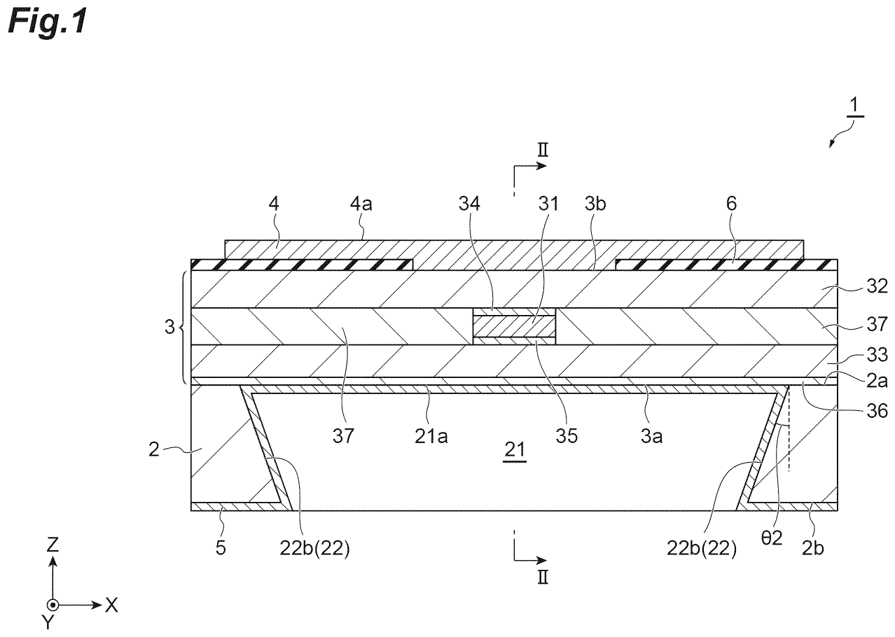

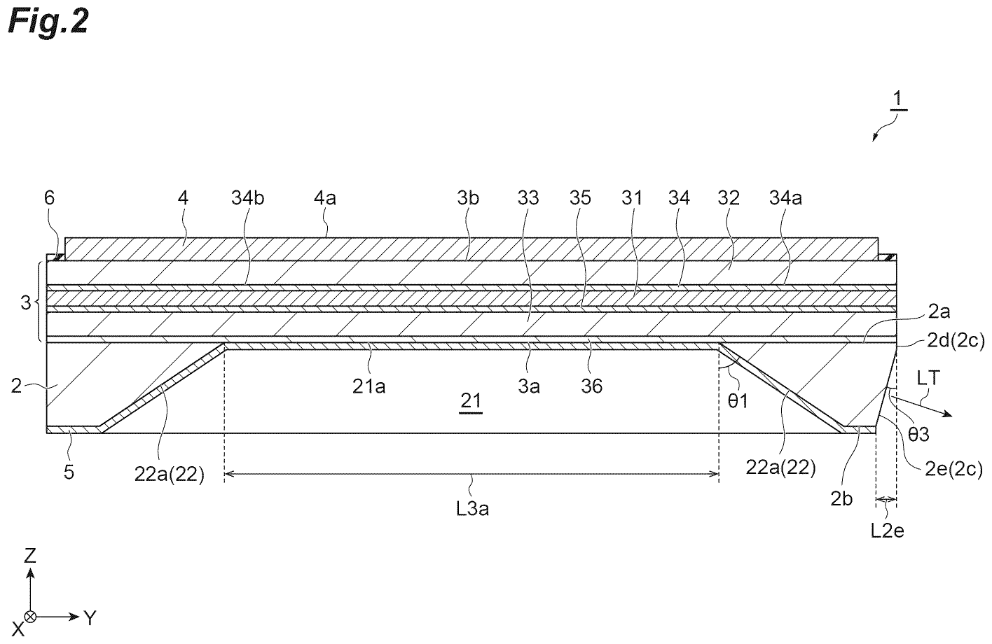

As illustrated in FIG. 1 and FIG. 2, a quantum cascade laser 1 includes a semiconductor substrate 2 (hereinafter, also referred to as “substrate 2”), a semiconductor stacked body 3 (hereinafter, also referred to as “stacked body 3”), a first electrode 4, and a second electrode 5. Hereinafter, a width direction of the substrate 2 is referred to as an X-direction, a longitudinal direction of the substrate 2 is referred to as a Y-direction, and a thickness direction of the substrate 2 is referred to as a Z-direction. As to be described later, the Y-direction is an oscillation direction of light in an active layer 31 included in the stacked body 3, and the Z-direction is a stacking direction in which a plurality of layers constituting the stacked body 3 are stacked. The quantum cascade laser 1 outputs output light LT that is a terahertz wave.

The substrate 2 is a rectangular plate-shaped InP substrate (single crystal substrate of indium phosphide). A carrier density in the substrate 2 is 1×10¹⁷ cm⁻³ or less, and the substrate 2 has an insulating property or a semi-insulating property. The substrate 2 may be an undoped InP substrate that is not doped with impurities, or may be a lightly doped InP substrate that is doped with impurities (for example, Fe) at a low concentration. The substrate 2 has transmitting properties for the output light LT. The carrier density in the substrate 2 may be 1×10¹⁶ cm⁻³ or less. In this case, absorption of the output light LT (terahertz wave) in the substrate 2 is almost eliminated. As the carrier density in the substrate 2 approaches 1×10¹⁷ cm⁻³ from 1×10¹⁶ cm⁻³, the absorption of the output light LT in the substrate 2 increases.

The substrate 2 has a first surface 2a (front surface), a second surface 2b (back surface) on a side opposite to the first surface 2a, and a substrate end surface 2c that connects the first surface 2a and the second surface 2b. For example, the first surface 2a and the second surface 2b are plat surfaces orthogonal to the Z-direction.

The substrate end surface 2c is an end surface of the substrate 2 in the Y-direction, and more specifically, an end surface on a side where the output light LT is emitted (a right side on FIG. 2). The substrate end surface 2c includes a vertical surface 2d that is orthogonal to the Y-direction (that is parallel to the Z-direction), and an inclined end surface 2e that is inclined to the Z-direction. The vertical surface 2d is connected to the first surface 2a, and the inclined end surface 2e is connected to the second surface 2b. The inclined end surface 2e is inclined with respect to the Z-direction toward an opposite side of the stacked body 3. That is, the inclined end surface 2e is inclined toward an inner side of the substrate 2 as approaching the second surface 2b. Here, the “inner side” is a center side of the substrate 2 in a plan view (when viewed from the Z-direction). In the quantum cascade laser 1, the output light LT is emitted from the inclined end surface 2e. That is, the inclined end surface 2e is an emission surface in the quantum cascade laser 1.

A concave portion 21 (through-hole) is formed in the second surface 2b of the substrate 2. The concave portion 21 passes through the substrate 2, and reaches the stacked body 3. According to this, on the bottom 21a of the concave portion 21, an exposed surface 3a of the stacked body 3 is exposed from the substrate 2.

Side surfaces 22 of the concave portion 21 include a pair of first inclined surfaces 22a and a pair of second inclined surfaces 22b. The pair of first inclined surfaces 22a are side surfaces in the Y-direction, and face each other in the Y-direction. One of the first inclined surfaces 22a is formed on a side surface on a side where the output light LT is emitted (a right side in FIG. 2) between the side surfaces 22 of the concave portion 21. The pair of second inclined surfaces 22b are side surfaces in the X-direction, and face each other in the X-direction. Each of the first inclined surfaces 22a is inclined with respect to the Z-direction to approach an outer edge of the substrate 2 as being far away from the stacked body 3. That is, the pair of first inclined surfaces 22a are formed in a forward tapered shape to approach each other as approaching the stacked body 3. Each of the second inclined surfaces 22b is inclined with respect to the Z-direction to be far away from the outer edge of the substrate 2 as being far away from the stacked body 3. That is, the pair of second inclined surfaces 22b are formed in a reverse tapered shape to be far away from each other as approaching the stacked body 3.

In the example, an inclination angle θ1 of the first inclined surfaces 22a with respect to the Z-direction is larger than an inclination angle θ3 of the inclined end surface 2e with respect to the Z-direction. The inclination angle θ1 of the first inclined surfaces 22a with respect to the Z-direction is larger than an inclination angle θ2 of the second inclined surfaces 22b with respect to the Z-direction. A length L3a of the exposed surface 3a of the stacked body 3 in the Y-direction is longer than a length L2e of the inclined end surface 2e in the Y-direction. As an example, the inclination angle θ1 of the first inclined surface 22a is approximately 60°, and the inclination angle θ2 of the second inclined surface 22b is approximately 20°. The inclined surfaces can be formed, for example, by anisotropic etching using a difference in an etching rate due to a crystal plane of the substrate 2. That is, a formation direction of the stacked body 3 (an oscillation direction of light in the active layer 31) is determined so that an orientation of the crystal plane of the substrate 2 conforms to a desired formation direction of the first inclined surfaces and the second inclined surfaces to form the stacked body 3, and then etching is performed from the second surface 2b side, thereby obtaining a surface with the above-described inclination angle. As an example, the inclination angle θ3 of the inclined end surface 2e is approximately 10°. The inclined end surface 2e is formed, for example, by polishing.

The stacked body 3 is formed on the first surface 2a of the substrate 2. The stacked body 3 includes the active layer 31, a first clad layer 32, a second clad layer 33, a first guide layer 34, a second guide layer 35, a contact layer 36, and a support layer 37. The contact layer 36, the second clad layer 33, the second guide layer 35, the active layer 31, the first guide layer 34, and the first clad layer 32 are sequentially stacked on the first surface 2a of the substrate 2 in this order. The support layer 37 is formed to sandwich the active layer 31, the first guide layer 34, and the second guide layer 35 in the X-direction. The first clad layer 32 and the second clad layer 33 are a pair of clad layers which sandwich the active layer 31 in the Z-direction. The respective layers constituting the stacked body 3 are formed on the substrate 2 by crystal growth using a metal-organic vapor phase epitaxy (MOVPE) method, a molecular beam epitaxy (MBE) method or the like. The first electrode 4 is formed on a surface 3b of the stacked body 3 on a side opposite to the substrate 2.

An example of a configuration of the stacked body 3 will be described. The contact layer 36 consists of InGaAs (Si-doping concentration: 1.5×10¹⁸ cm⁻³), and has a thickness of approximately 400 nm. The contact layer 36 is formed on the first surface 2a of the substrate 2. Each of the first clad layer 32 and the second clad layer 33 consists of InP (Si-doping concentration: 1.5×10¹⁶ cm⁻³), and has a thickness of approximately 5 μm. The first guide layer 34 consists of InGaAs (Si-doping concentration: 1.5×10¹⁶ cm⁻³), and has a thickness of approximately 450 nm. The second guide layer 35 consists of InGaAs (Si-doping concentration: 1.5×10¹⁶ cm⁻³), and has a thickness of approximately 250 nm. The support layer 37 is an InP layer doped with Fe, and is disposed between the first clad layer 32 and the second clad layer 33 on both sides of the active layer 31, the first guide layer 34, and the second guide layer 35 in the X-direction. A contact layer may be formed between the first clad layer 32 and the first electrode 4. The contact layer may consist of InGaAs (Si-doping concentration: 1.5×10¹⁸ cm⁻³), and may have a thickness of approximately 15 nm.

A diffraction grading structure that functions as a distributed feedback (DFB) structure is formed in the first guide layer 34 along the Y-direction that is an oscillation direction of first pump light and second pump light (details thereof will be described later). The first guide layer 34 includes a first diffraction lattice structure 34a and a second diffraction lattice structure 34b arranged in the Y-direction as the diffraction lattice structure. The first diffraction lattice structure 34a oscillates the first pump light in a single mode, and the second diffraction lattice structure 34b oscillates the second pump light in a single mode. The first diffraction lattice structure 34a and the second diffraction lattice structure 34b are configured, for example, by forming a plurality of grooves extending in the X-direction to be arranged at a constant pitch in the Y-direction. The pitch of the grooves is different between the first diffraction lattice structure 34a and the second diffraction lattice structure 34b.

The active layer 31 extends along the Y-direction. For example, the active layer 31 includes a unit stacked body stacked in a plurality of stages, and has a multiple quantum well structure. The multiple quantum well structure includes a plurality of well layers consisting of InGaAs and a plurality of barrier layers consisting of InAlAs. The active layer 31 has a cascade structure in which a quantum well light-emitting layer used for generating light and an electron injection layer used for injecting electrons into the light-emitting layer are stacked alternately in a plurality of stages. More specifically, a semiconductor stacked structure including a light-emitting layer and an injection layer is set as a unit stacked body for one period, and the unit stacked body is stacked in a plurality of stages to form the active layer 31 having a cascade structure. The number of unit stacked bodies stacked is appropriately set in correspondence with a specific configuration, characteristics, and the like of a laser element.

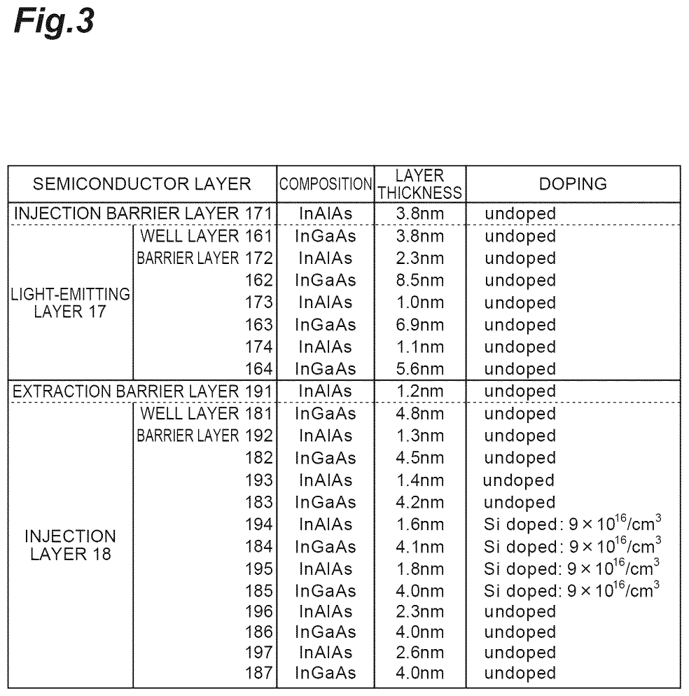

In an example illustrated in FIG. 3, the active layer 31 is formed by stacking unit stacked bodies including a quantum well light-emitting layer 17 and an electron injection layer 18. Unit stacked bodies for one period are formed as a quantum well structure in which eleven quantum well layers 161 to 164, 181 to 187, and eleven quantum barrier layers 171 to 174, 191 to 197 are stacked alternately. For example, the quantum well layers are constituted by an InGaAs layer that is lattice-matched with the substrate 2 consisting of InP, and the quantum barrier layers are constituted by an InAlAs layer that is lattice-matched with the substrate 2.

A stacked portion including the well layers 161 to 164 and the barrier layers 171 to 174 mainly functions as the quantum well light-emitting layer 17. A stacked portion including the well layers 181 to 187 and the barrier layers 191 to 197 mainly functions as the electron injection layer 18. Among the semiconductor layers of the quantum well light-emitting layer 17, a first stage of quantum barrier layer 171 functions as an injection barrier layer for electrons injected from the electron injection layer 18 to the quantum well light-emitting layer 17. Among the semiconductor layers of the electron injection layer 18, a first stage of quantum well layer 161 functions as an exit barrier layer for electrons from the quantum well light-emitting layer 17 to the electron injection layer 18. The quantum well layer 161 may not function as the exit barrier layer.

When a bias is applied between the first electrode 4 and the second electrode 5, injection of electrons, light-emitting transition of electrons, and relaxation of electrons are repeated in a plurality of unit stacked bodies of the active layer 31, and cascade light generation occurs. When electrons move in a cascade manner in the plurality of unit stacked bodies, first pump light having a first frequency Ω₁ and second pump light having a second frequency ω₂ are generated due to the intersubband light-emitting transition of electrons in each of the unit stacked body. The first pump light and the second pump light which have been generated oscillate between a pair of end surfaces 31a of the active layer 31 in the Y-direction. That is, the pair of end surfaces 31a of the active layer 31 constitute a resonator that oscillates the first pump light and the second pump light. The first pump light is oscillated in a single mode by the above-described first diffraction lattice structure 34a, and the second pump light is oscillated in a single mode due to the above-described second diffraction lattice structure 34b. Then, a terahertz wave (output light LT) having a difference frequency (|ω₁−ω₂|) between the first frequency ω₁ and the second frequency ω₂ is generated by difference frequency generation (DFG) due to Cherenkov phase matching. For example, the first pump light and the second pump light are mid-infrared light, and a frequency range of the generated terahertz wave is 1 THz to 6 THz.

In the quantum cascade laser 1, the Cherenkov phase matching is used to generate and output light of the difference frequency. The Cherenkov phase matching is a pseudo-phase matching method, and the output light LT is radiated in a direction inclined with respect to a traveling direction (Y-direction) of the first pump light and the second pump light. Therefore, in the quantum cascade laser 1, the output light LT is emitted from the inclined end surface 2e inclined with respect to the Y-direction. The output light LT is transmitted through the substrate 2 and is emitted to the outside.

The first electrode 4 is a front surface electrode formed on the surface 3b of the stacked body 3 on a side opposite the substrate 2. The surface 3b may be constituted by the first clad layer 32 or the contact layer described above. The first electrode 4 is formed by a metal material having electrical conductivity. An insulating layer 6 is formed on the surface 3b of the stacked body 3. The insulating layer 6 is formed so as to expose the surface 3b at the central portion in the X-direction, and the first electrode 4 is in contact with the stacked body 3 at the exposed portion and is electrically connected thereto. The surface 4a of the first electrode 4 on a side opposite the stacked body 3 is flat. According to this, epi-side-down mounting in which the quantum cascade laser 1 is mounted on a mounting target (for example, a submount) so that the first electrode 4 faces the mounting surface of the mounting target can be performed in a satisfactory manner.

The second electrode 5 is a back surface electrode formed on the second surface 2b of the substrate 2. The first electrode 4 is formed by a metal material having electrical conductivity. The second electrode 5 is continuously formed on the second surface 2b of the substrate 2, on the side surfaces 22 (first inclined surfaces 22a and second inclined surfaces 22b) of the concave portion 21, and on the exposed surface 3a of the stacked body 3 exposed from the substrate 2 at the bottom 21a of the concave portion 21. The exposed surface 3a is constituted, for example, by the contact layer 36. In this example, the second electrode 5 is continuously formed on the entire second surface 2b, the entire side surface 22, and the entire exposed surface 3a. Since the output light LT is reflected by the second electrode 5 formed by a metal material on the second surface 2b, the side surfaces 22, and the exposed surface 3a, the output light LT is not emitted from the second surface 2b, the side surfaces 22, and the exposed surface 3a. The second electrode 5 is in contact with the stacked body 3 (contact layer 36) on the exposed surface 3a and is electrically connected thereto. In order to secure the intensity of the quantum cascade laser 1, the thickness of the second electrode 5 is preferably, for example, 3 μm or more.

### Function and Effect

In the quantum cascade laser 1, the stacked body 3 including the active layer 31 is formed on the substrate 2 constituted by an InP substrate with a carrier density of 1×10¹⁷ cm⁻³ or less. Since the substrate 2 is less likely to absorb a terahertz wave, in the quantum cascade laser 1, the terahertz wave (output light LT) generated by difference frequency generation can be transmitted through the substrate 2 and emitted. On the other hand, since an InP substrate with a carrier density of 1×10¹⁷ cm⁻³ or less has insulating or semi-insulating properties, when such a semiconductor substrate is used, a pair of electrodes (anode and cathode) has been provided on a first surface side (semiconductor stacked body side) of the semiconductor substrate. However, in that case, a configuration of the first surface side may become complicated. For example, it is necessary to provide a separation groove in the semiconductor stacked body for electrical insulation between the pair of electrodes, and a manufacturing process may become complicated. In addition, since a configuration of the first surface side becomes complicated, there is a concern that mounting on the first surface side (epi-side down mounting) to a mounting target may be inappropriate. In contrast, in the quantum cascade laser 1, the second electrode 5 is formed on the second surface 2b of the substrate 2. More specifically, the concave portion 21 that passes through the substrate 2 and reaches the stacked body 3 is formed in the second surface 2b of the substrate 2, and the second electrode 5 is continuously formed on the second surface 2b of the substrate 2, on the side surfaces 22 of the concave portion 21, and on the exposed surface 3a of the stacked body 3 which is exposed from the substrate 2 at the bottom 21a of the concave portion 21. When providing the second electrode 5 on the second surface 2b side of the substrate 2 in this manner, the configuration of the first surface 2a side can be simplified as compared with a case where both the first electrode 4 and the second electrode 5 are provided on the first surface 2a side. In addition, since the second electrode 5 is continuously formed on the second surface 2b of the substrate 2, on the side surfaces 22 of the concave portion 21, and on the exposed surface 3a of the stacked body 3, a strength as an element can be improved. Therefore, according to the quantum cascade laser 1, the structure can be simplified and the strength can be improved.

In the quantum cascade laser 1, the stacked body 3 is formed thickly mainly due to the thickness of the clad layer as compared with other semiconductor lasers (for example, semiconductor lasers emitting near-infrared light, and the like). For example, the stacked body 3 has a thickness of approximately 10 μm. Therefore, the strength of the stacked body 3 is relatively high. Since the strength of the stacked body 3 is relatively high in this way, the quantum cascade laser 1 can maintain the strength even when the concave portion 21 is formed in the substrate 2 or the exposed surface 3a is formed widely. Furthermore, the strength can be supplemented by the second electrode 5 continuously formed on the second surface 2b of the substrate 2, on the side surfaces 22 of the concave portion 21, and on the exposed surface 3a of the stacked body 3.

The side surfaces 22 of the concave portion 21 includes the first inclined surfaces 22a inclined with respect to the Z-direction (stacking direction of the stacked body 3) so as to approach the outer edge of the substrate 2 as being far away from the stacked body 3. According to this, it is possible to suppress occurrence of step discontinuities (fracture at a step portion) in the second electrode 5 continuously formed on the second surface 2b of the substrate 2, the side surfaces 22 of the concave portion 21, and the exposed surface 3a of the stacked body 3.

The substrate end surface 2c of the substrate 2 includes the inclined end surface 2e inclined with respect to the Z-direction so as to face the opposite side of the stacked body 3, and the inclination angle θ1 of the first inclined surface 22a with respect to the Z-direction is larger than the inclination angle θ3 of the inclined end surface 2e with respect to the Z-direction. According to this, the substrate end surface 2c can be used as an emission surface from which the output light LT is emitted. In addition, occurrence of step discontinuities in the second electrode 5 can be further suppressed.

The length L3a of the exposed surface 3a of the stacked body 3 in the Y-direction (oscillation direction of light of the first frequency (first pump light) and light of the second frequency (second pump light) in the active layer 31) is longer than the length L2e of the inclined end surface 2e in the Y-direction. According to this, the second electrode 5 can be brought into contact with the stacked body 3 over a long distance in the Y-direction, and the second electrode 5 and the stacked body 3 can be electrically connected to each other in a satisfactory manner.

Each of the first inclined surfaces 22a is formed on a side surface from which the output light LT is emitted among the side surfaces 22 of the concave portion 21. According to this, it is possible to secure a large size (length) along an oscillation direction of a portion of the stacked body 3 on a side from which the output light LT is emitted. When using the portion as a transmission path for the output light LT generated in the active layer 31, the output light LT can be emitted in a satisfactory manner.

The side surfaces 22 of the concave portion 21 includes the second inclined surfaces 22b inclined with respect to the Z-direction so as to be far away from the outer edge of the substrate 2 as being far away from the stacked body 3. Since the second inclined surfaces 22b are formed, the exposed surface 3a of the stacked body 3 can be widened. As a result, the second electrode 5 can be brought into contact with the stacked body 3 over a wide range, and the second electrode 5 and the stacked body 3 can be electrically connected to each other in a satisfactory manner.

The inclination angle θ1 of the first inclined surfaces 22a with respect to the Z-direction is smaller than the inclination angle θ2 of the second inclined surfaces 22b with respect to the Z-direction. According to this, it is possible to further suppress occurrence of step discontinuities in the second electrode 5. That is, first, since the inclination angle θ1 is large, it is possible to suppress occurrence of step discontinuities in the second electrode 5 when forming the second electrode 5. In addition, for example, when forming the second electrode 5 by evaporation from a back side (a lower side in FIG. 1), when the inclination angle θ2 of the second inclined surfaces 22b is large, the second inclined surfaces 22b may hinder the evaporation, and the second electrode 5 may not be formed in a satisfactory manner up to a boundary portion between the second inclined surfaces 22b and the exposed surface 3a. In contrast, in this embodiment, since the inclination angle θ2 is small, it is possible to suppress occurrence of such a situation.

The surface 4a of the first electrode 4 on a side opposite to the stacked body 3 is flat. According to this, epi-side-down mounting in which the quantum cascade laser 1 is mounted on a mounting target so that the first electrode 4 faces the mounting surface of the mounting target can be performed in a satisfactory manner.

### MODIFICATION EXAMPLE

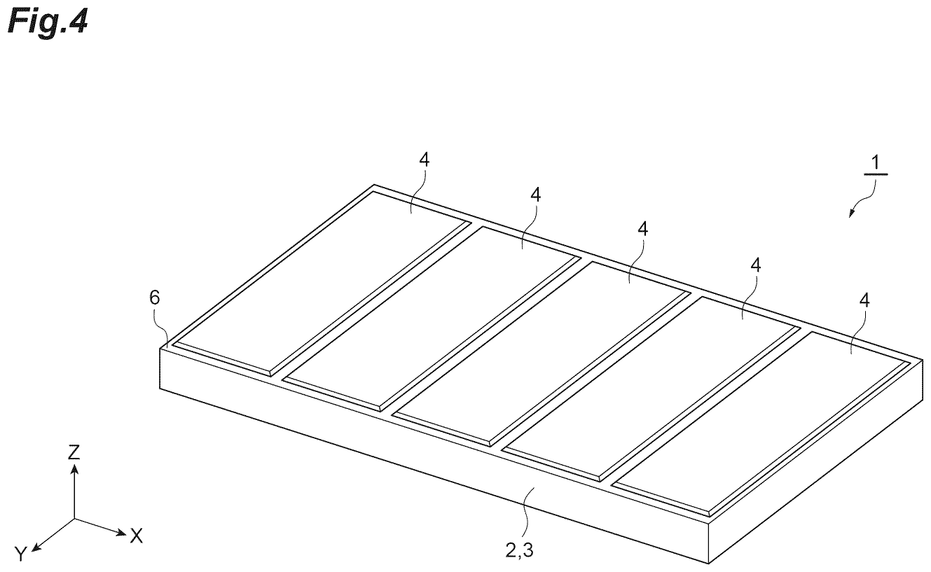

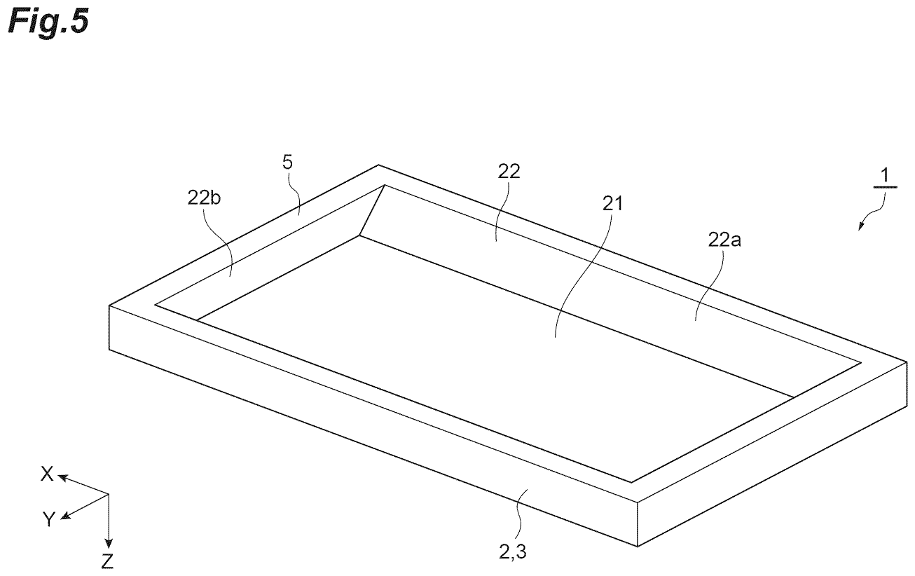

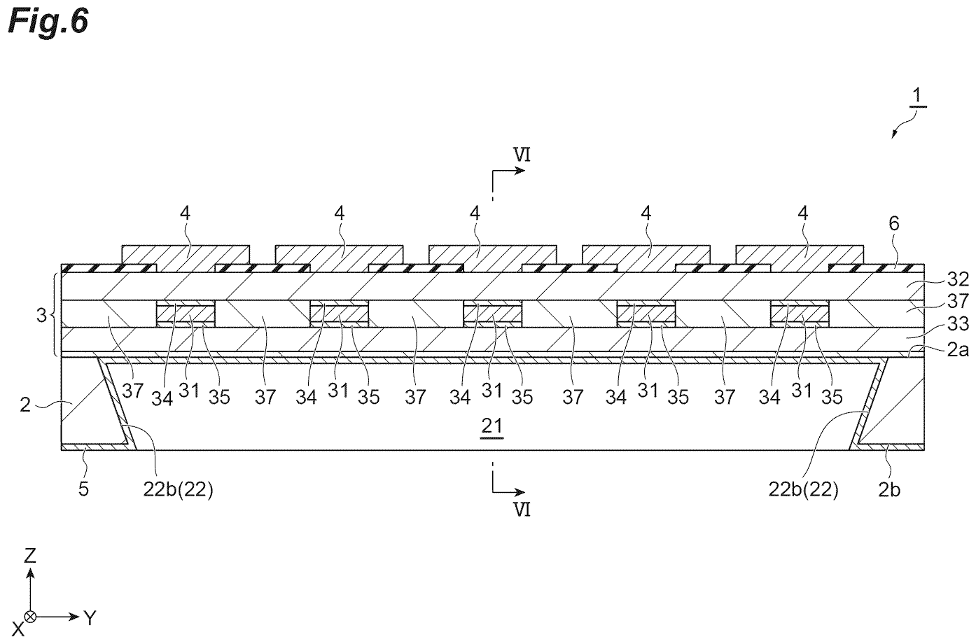

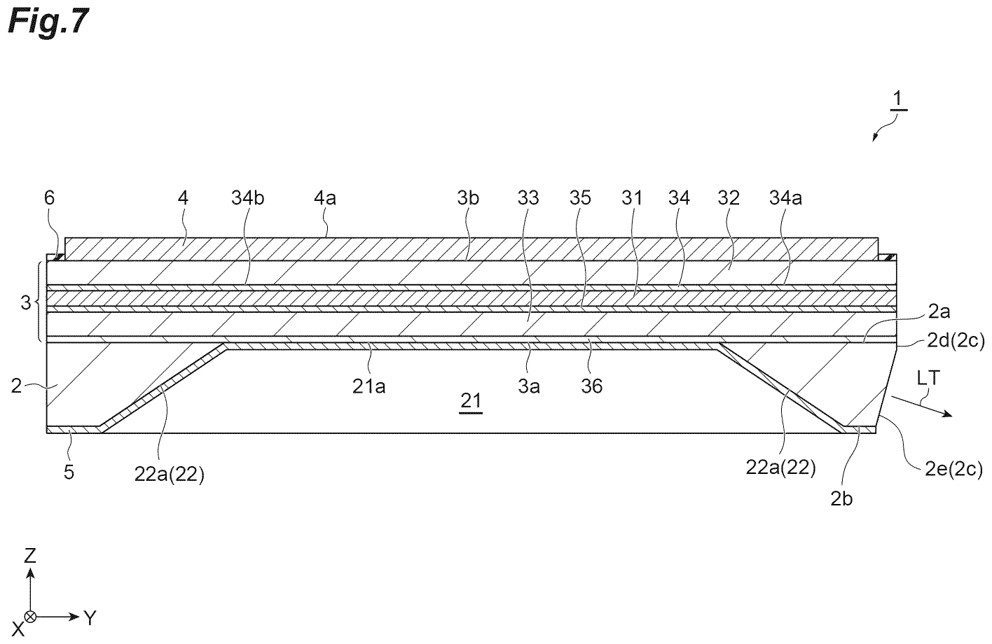

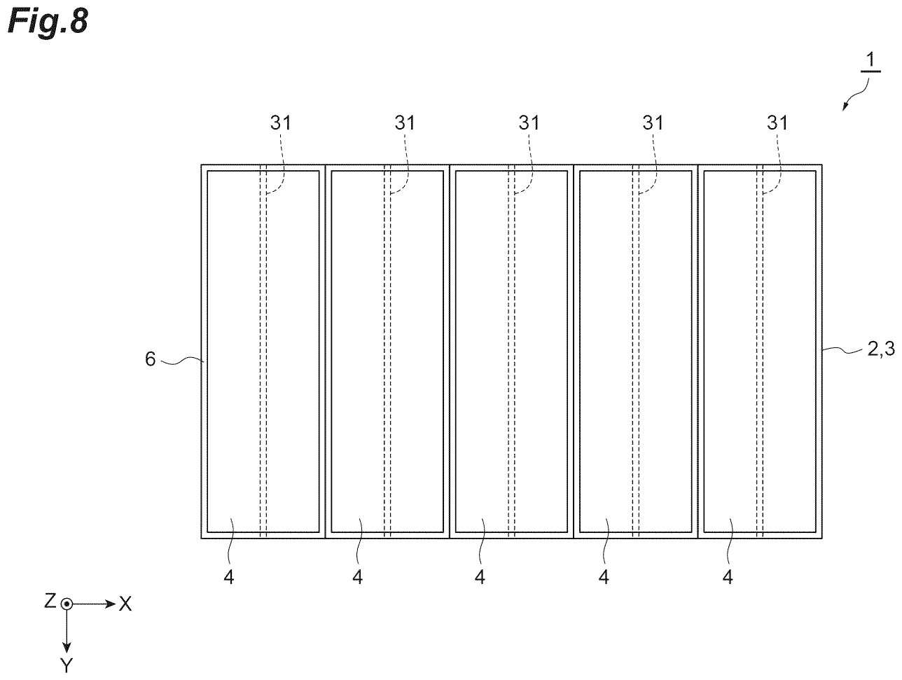

As in a quantum cascade laser 1 of a modification example as illustrated in FIG. 4 to FIG. 8, the stacked body 3 may be formed on the substrate 2 so that a plurality of the active layers 31 are arranged along the X-direction (a direction orthogonal to the stacking direction of the stacked body 3). In the modification example, the stacked body 3 includes the plurality of (five in this example) active layers 31 extending along the Y-direction. The plurality of active layers 31 are arranged at regular intervals along the X-direction. A plurality of (five in this example) first electrodes 4 corresponding to the plurality of active layers 31 are formed on the surface 3b of the stacked body 3. The plurality of first electrodes 4 are arranged so as to overlap the plurality of active layers 31 in the Z-direction. The concave portion 21 is formed so as to overlap the plurality of active layers 31 in a plan view. That is, one piece of the concave portion 21 is formed in the substrate 2, and the one piece of the concave portion 21 overlaps all of the active layers 31.

Even with such a modification example, the structure can be simplified and the strength can be improved as in the above-described embodiment. In addition, the quantum cascade laser 1 including the plurality of active layers 31 can be constituted in a satisfactory manner. The quantum cascade laser 1 may be driven and used so that the output light LT is generated, for example, in only one of the plurality of active layers 31, or may be driven and used so that the output light LT is generated in two or more (for example, all) of the plurality of active layers 31.

The present disclosure is not limited to the above-described embodiment and modification example. For example, the materials and shapes of respective configurations are not limited to the materials and the shapes described above, and various materials and shapes can be employed.

In the above-described embodiment, each of the first inclined surfaces 22a is formed on a side surface (side surface in the Y-direction) on a side where the output light LT is emitted among the side surfaces 22 of the concave portion 21, but the first inclined surface 22a may be formed on a side surface of the concave portion 21 in the X-direction. In the above-described embodiment, each of the second inclined surfaces 22b is formed on a side surface in the X-direction among the side surfaces 22 of the concave portion 21, but the second inclined surface 22b may be formed on a side surface of the concave portion 21 in the Y-direction. The side surfaces 22 may not include the first inclined surface 22a. The side surfaces 22 may not include the second inclined surface 22b. For example, any or all of the side surfaces 22 may be parallel to the Z-direction.

The inclination angle θ1 of the first inclined surface 22a may be equal to or smaller than the inclination angle θ3 of the inclined end surface 2e. The substrate end surface 2c of the substrate 2 may not include the inclined end surface 2e, and the entire substrate end surface 2c may be the vertical surface 2d. The substrate end surface 2c of the substrate 2 may not include the vertical surface 2d, and the entire substrate end surface 2c may be the inclined end surface 2e. The length L3a of the exposed surface 3a of the stacked body 3 may be equal to or smaller than the length L2e of the inclined end surface 2e in the Y-direction. The surface 4a of the first electrode 4 may not necessarily be flat. The second electrode 5 may not be formed over the entire second surface 2b, the entire side surfaces 22, and the entire exposed surface 3a, and may be formed, for example, on a part of the second surface 2b or on a part of the exposed surface 3a. However, when the second electrode 5 is formed over the entire surfaces, it is advantageous for securement of the strength and electrical conductivity.

What is claimed is:

1. A quantum cascade laser, comprising:
a semiconductor substrate including a first surface, and a second surface on a side opposite to the first surface;
a semiconductor stacked body that includes an active layer having a cascade structure and is formed on the first surface of the semiconductor substrate, wherein the active layer is configured to generate and oscillate light of a first frequency and light of a second frequency, and generate a terahertz wave having a difference frequency between the first frequency and the second frequency by difference frequency generation;
a first electrode formed on a surface of the semiconductor stacked body on a side opposite to the semiconductor substrate; and
a second electrode formed on the second surface of the semiconductor substrate,
wherein the semiconductor substrate is an InP substrate with a carrier density of 1×10¹⁷ cm⁻³ or less,
a concave portion that passes through the semiconductor substrate and reaches the semiconductor stacked body is formed in the second surface of the semiconductor substrate, and
the second electrode is continuously formed on the second surface of the semiconductor substrate, on side surfaces of the concave portion, and on an exposed surface of the semiconductor stacked body which is exposed from the semiconductor substrate at the bottom of the concave portion.

2. The quantum cascade laser according to claim 1,
wherein the side surfaces of the concave portion include a first inclined surface inclined with respect to a stacking direction of the semiconductor stacked body so as to approach an outer edge of the semiconductor substrate as being far away from the semiconductor stacked body.

3. The quantum cascade laser according to claim 2,
wherein the semiconductor substrate further includes a substrate end surface that connects the first surface and the second surface,
the substrate end surface includes an inclined end surface inclined with respect to the stacking direction to face a side opposite to the semiconductor stacked body, and
an inclination angle of the first inclined surface with respect to the stacking direction is larger than an inclination angle of the inclined end surface with respect to the stacking direction.

4. The quantum cascade laser according to claim 3,
wherein a length of the exposed surface of the semiconductor stacked body in an oscillation direction of the light of the first frequency and the light of the second frequency in the active layer is longer than a length of the inclined end surface in the oscillation direction.

5. The quantum cascade laser according to claim 2,
wherein the first inclined surface is formed on a side surface from which the terahertz wave is emitted among the side surfaces of the concave portion.

6. The quantum cascade laser according to claim 1,
wherein the side surfaces of the concave portion include a second inclined surface inclined with respect to a stacking direction of the semiconductor stacked body so as to be far away from an outer edge of the semiconductor substrate as being far away from the semiconductor stacked body.

7. The quantum cascade laser according to claim 1,
wherein the side surfaces of the concave portion include a first inclined surface inclined with respect to a stacking direction of the semiconductor stacked body so as to approach an outer edge of the semiconductor substrate being far away from the semiconductor stacked body, and a second inclined surface inclined with respect to the stacking direction of the semiconductor stacked body so as to be far away from an outer edge of the semiconductor substrate as being far away from the semiconductor stacked body, and
an inclination angle of the first inclined surface with respect to the stacking direction is larger than an inclination angle of the second inclined surface with respect to the stacking direction.

8. The quantum cascade laser according to claim 1,
wherein the semiconductor stacked body is formed on the semiconductor substrate so that a plurality of the active layers are arranged in a direction orthogonal to a stacking direction of the semiconductor stacked body, and
the concave portion is formed so as to overlap the plurality of active layers when viewed from the stacking direction.

9. The quantum cascade laser according to claim 1,
wherein a surface of the first electrode on a side opposite to the semiconductor stacked body is flat.
